(19) United States
(12) Patent Application Publication
(10) Pub. No.: US 2026/0276887 A1
(43) Pub. Date: Sep. 17, 2026

(54) SYSTEM AND METHODS FOR MULTI-DEVICE PHOTONIC PACKAGE

(71) Applicant: Samsung Electronics Co., Ltd., Suwon-si (KR)

(72) Inventor: Hamid ESLAMPOUR, San Jose, CA (US)

(21) Appl. No.: 19/315,467

(22) Filed: Aug. 29, 2025

Related U.S. Application Data
(60) Provisional application No. 63/770,337, filed on Mar. 11, 2025.

(51) Int. Cl. G02B 6/12

(52) U.S. Cl. CPC G02B 6/12004

(57) ABSTRACT

Disclosed herein are methods, devices and systems including a substrate supporting one or more processing units and one or more optical engines, the substrate coupling the one or more processing units and the one or more optical engines. The one or more optical engines include a first near compute device and a first bi-directional optical coupler, and the one or more optical engines may convert an incoming optical signal received by the first bi-directional optical coupler to an electrical signal, and the one or more optical engines may route the electrical signal to the first near compute device or the one or more processing units via the one or more optical engines

### CROSS-REFERENCE TO RELATED APPLICATION

This application claims the priority benefit under 35 U.S.C. § 119(e) of U.S. Provisional Patent Application Serial No. 63/770,337, filed on Mar. 11, 2025, the disclosure of which is incorporated herein by reference in its entirety.

### TECHNICAL FIELD

The subject matter disclosed herein relates to microelectronics and integrated circuit (IC) structures. More particularly, the subject matter disclosed herein relates to a technique for co-packaging electronic integrated circuits (EICs) and photonic integrated circuits (PICs).

### BACKGROUND

Semiconductor devices may be created using complex structures made up of sets of smaller components, which may be referred to as packages. Packaging describes the general method for connecting and integrating multiple computational components together in an integrated unit and may involve multiple different types of integrated circuits on multiple substrates, which may combine into a single unit. Packaging may also describe a method for which multiple computational components within a single unit are protected by the use of various techniques to provide thermal, physical and electrical protection.

It is further noted that background concepts discussed herein are for informational purposes only and are not intended to limit the present disclosure, nor should the background or field described be intended to limit the disclosure herein to a particular use or concept.

### SUMMARY

An example embodiment provides a device with a substrate supporting one or more processing units and one or more optical engines, the substrate coupling the one or more processing units and the one or more optical engines. The one or more optical engines may include a first near compute device and a first bi-directional optical coupler. The one or more optical engines may convert an incoming optical signal received by the first bi-directional optical coupler to an electrical signal, and the one or more optical engines may route the electrical signal to the first near compute device or the one or more processing units via the one or more optical engines. The one or more optical engines may include at least a first photonic circuit and a first electrical circuit, and the first photonic may include at least one of waveguide, an optical filer, a polarizer, a serializer, a phase shift, couplers, and a grating. The first electric circuit may include at least one of a photodetector, a transimpedance amplifier, and an analog-to-digital converter. The one or more optical engines may include a first optical engine and a second optical engine, the first optical engine may include the first near compute device and first bi-directional optical coupler, and the second optical engine may include a second near compute device and a second bi-directional optical coupler. The first optical engine may route a first incoming optical signal received by the first bi-directional optical coupler to the first near compute device of the one or more processing units, and the second optical engine may route a second incoming optical signal received by the second bi-directional coupler to the second near compute device or the one or more processing units. The one or more optical engines may have at least a first physical layer and a second physical layer, and the first physical layer may be coupled to the first near compute device, and the second physical layer may be coupled to the one or more processing units. The one or more optical engines may include a first photonic circuit and a first electronic circuit, and the first electronic circuit may be on the surface of the one or more optical engines between the first photonic circuit and the first near compute device. The first near compute device may be communicatively coupled to a second near compute device via an optical fiber. The first near compute device may include at least one of a memory device and a processing device.

An example embodiment provides a device with a substrate supporting a first processing unit, a first optical engine and a second optical engine. The substrate may couple the first processing unit, the first optical engine, and the second optical engine. The first optical engine may include a first near compute device and a first bi-directional optical coupler, and the second optical engine may include a second near compute device and a second bi-directional coupler. The first optical engine may route a first optical signal received by the first bi-directional optical coupler to the first near compute device or the first processing unit. The second optical engine may route a second optical signal received by the second bi-directional optical coupler to the second near compute device or the first processing unit. The first optical engine may include a first photonic circuit and a first electronic circuit, and the first electronic circuit may be on a surface of the first optical engine between the first photonic circuit and the first near compute device. The first optical engine engines may include at least a first photonic circuit and a first electrical circuit, and the first photonic may include at least one of waveguide, an optical filer, a polarizer, a serializer, a phase shift, couplers, and a grating. The first electric circuit may include at least one of a photodetector, a transimpedance amplifier, and an analog-to-digital converter. The first near compute device may be communicatively coupled to a third near compute device via the first bi-directional optical coupler. The first optical engine may include a first physical layer and a second physical layer, the first physical layer may be coupled to the first near compute device, and the second physical layer may be coupled to the first processing unit. The second optical engine may include a third physical layer and a fourth physical layer, the third physical layer may be coupled to the second near compute device, and the fourth physical layer may be coupled to the first processing unit. The first near compute device may include at least one of a memory device and a processing device.

An example embodiment provides a system including a first package and a second package. The first package may include a first optical engine and a first processing unit, and the first optical engine may include a first near compute device. The second package may include a second optical engine and a second processing unit, and the second optical engine may include a second near compute device. A first optical switch may be coupled to the first package via a first connection and the first optical switch coupled to the second package via second connection. The first package may be optically coupled to the second package via the first optical engine and the second optical engine. The first connection may couple the first optical switch to a first photonic integrated circuit on the first package, and the second connection may couple the first optical switch to a second photonic integrated circuit on the second package. An optical coupling between the first package and the second package may transmit a read signal to the first processing unit and a write signal to the first near compute device. An optical coupling between the first package and the second package may transmit a write signal to the first processing unit and a write signal to the first near compute device. The first near compute device or the second near compute device may include at least one memory device and at least one processing device. The first optical engine may include a first bi-directional optical coupler and the second optical engine may include a second bi-directional coupler, such that the first bi-directional optical coupler may optically couple to the second bi-directional optical coupler. The first connection may be an optical connection. The second connection may be an optical connection.

### BRIEF DESCRIPTION OF THE DRAWING

In the following section, the aspects of the subject matter disclosed herein will be described with reference to example embodiments illustrated in the figures, in which:

FIG. 1 depicts a plan view of a semiconductor structure including a 2 x 4 package structure with two processing units, two support photonic circuits, and four monolithic optical engines according to various embodiments of the subject matter disclosed herein;

FIG. 2 depicts a plan view of a semiconductor structure including a 1 x 2 package structure with one processing unit, two support photonic circuits, and two monolithic optical engines according to various embodiments of the subject matter disclosed herein;

FIG. 3 depicts a plan view of a monolithic optical engine according to various embodiments of the subject matter disclosed herein;

FIG. 4 depicts a cross-sectional view of the semiconductor structure of either FIGS. 1 or 2 along lines A-A’ according to various embodiments of the subject matter disclosed herein;

FIG. 5 depicts a plan view of a semiconductor system demonstrating the interconnection between a center package and surrounding packages and switches according to various embodiments of the subject matter disclosed herein;

FIG. 6 depicts a plan view of a semiconductor system demonstrating the interconnection between a two package and two switches according to various embodiments of the subject matter disclosed herein;

FIG. 7 depicts a plan view of a semiconductor structure showing the communications routing for a package receiving communications to a processing unit via a monolithic optical engine according to various embodiments of the subject matter disclosed herein;

FIG. 8 depicts a plan view of a semiconductor structure showing the communications routing for a package receiving communications to the near compute device via a monolithic optical engine according to various embodiments of the subject matter disclosed herein;

FIG. 9 depicts a plan view of a semiconductor structure showing the communications routing for a package receiving communications to the processing unit via a supporting photonic circuit according to various embodiments of the subject matter disclosed herein;

FIG. 10 depicts a plan view of a semiconductor structure showing communications routing for a package transmitting via the monolithic optical engine according to various embodiments of the subject matter disclosed herein; and

FIG. 11 depicts a flow chart demonstrating a method of assembling a semiconductor structure such those of FIG. 1-10 according to various embodiments of the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms, and a plural term may include the corresponding singular form. Similarly, a hyphenated term (e.g., “two-dimensional,” “pre-determined,” etc.) may be occasionally interchangeably used with a corresponding non-hyphenated version (e.g., “two dimensional,” “predetermined, etc.), and a capitalized entry (e.g., “Counter Clockwise,” “Three-Dimensional,” etc.) may be interchangeably used with a corresponding non-capitalized version (e.g., “counter clockwise,” “three-dimensional,” etc.). Such occasional interchangeable uses shall not be considered inconsistent with each other.

Also, depending on the context of discussion herein, a singular term may include the corresponding plural forms, and a plural term may include the corresponding singular form. It is further noted that various figures(including component diagrams) shown and discussed herein are for illustrative purpose only and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

The term “surround” (as in “a first object surrounds a second object”) as used herein describes the first object enclosing or is formed around or over the second object, or the first object accommodates, conforms, follows, aligns, or follows the path of the second object.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, EICs refer to a wide variety of integrated circuits using electrical components. In some embodiments, EICs may include a combination of various electrical components such as transistors, resistors, inductors, and capacitors, which in combination form an electronic circuit on a substrate. In some embodiments, EICs may be referred to in terms such as microchips, microcontrollers, silicon chips, and near compute devices. In some embodiments, EICs may include central processing units (CPUs), logic chips, memory such as static random-access memory (SRAM), dynamic random-access memory (DRAM), synchronous dynamic random-access memory (SDRAM), double data rate DRAM or DDR DRAM, application processors (AP), auxiliary processing units (XPUs), graphical processing units (GPUs), artificial intelligence (AI) chips, high bandwidth memory (HBM), and other application-specific integrated circuits (ASIC). In some embodiments, a combination of circuits may be present on a substrate. As used herein, an XPU may refer to an auxiliary processing unit designed to perform specialized or dedicated processing optimized for conducting specific tasks more efficiently than a general processing unit such as a CPU and may be also referred to as a data processing unit (DPU), infrastructure processing unit (IPU), function accelerator card (FAC), network attached processing unit (NAPU).

As used herein, PICs refer to a wide variety of integrated circuits using photonic components. In some embodiments, PICs may include a combination of various photonic components such as waveguides, optical filters, phase shifters, gratings, lenses, mirrors, and optical ring resonators. In some embodiments, PICs may include electrical components such as photodiodes, light emitting diodes, and laser diodes. In some embodiments, PICs may be referred to using terms such as optical engines, optical engines, integrated optical circuits, and planar light wave circuits.

As used herein substrates may refer to a variety of materials and structures, including wafers using silicon, wafers using silicon on an insulator (SOI) such as glass, wafers of other semiconductor materials such as germanium, as well as other semiconductor materials on an insulator. In some embodiments, a substrate may include an organic material. In some embodiments, the substrates may be referred to as wafers, dies, and chips alone or in combination. Bonding substrates may be thus known, in some embodiments, as die-to-die (D2D) bonding, wafer-to-wafer bonding (W2W) or die-to-wafer bonding (D2W). In some embodiments, a packaged chip may contain multiple substrates. In some embodiments, a packaged chip may contain multiple substrates, and may include PIC substrates, EIC substrates, or a combination of PIC substrates and EIC substrates. In some embodiments, circuits may be bonded directly facing each other, while in other embodiments a flip-chip bonding may be used. In some embodiments, interconnections may be made between substrates on a front or circuit side of the substrate. In other embodiments, interconnections may be made on a rear or back side of the substrate opposite from the circuit structure. In some embodiments, an interconnection may include through-substrate vias (TSVs) or other forms of through-chip vias where one or more substrates may be connected using a via extending through an interposer such as another substrate or chip. In some embodiments, an interconnection may be formed using connections on a surface of a substrate, such as a pad, and may use additional materials between the pads such as solder to form an interconnection.

As used herein, multiplexing may refer to a number of techniques for multiplexing optical signals. In some embodiments, multiplexing may refer to wavelength division multiplexing (WDM). In some embodiments, the multiplexing may refer to polarization-based multiplexing. In some embodiments, the multiplexing may refer to optical fiber mode based polarization. In some embodiments, multiplexing may be a combination of one or more of WDM, polarization, and fiber mode polarization.

As used herein, polarization may refer to both linear and circular polarization. Linear polarization modes may be referred to as S and P or transverse-magnetic (TM) and transverse-electric (TE) polarizations. Circular polarizations may be referred to as right-handed polarization (RCP) or left-handed polarization (RCP).

As used herein packaging refers to a process of forming interconnections between substrates. In some embodiments, the interconnections may be between direct surfaces and involve W2W, D2D, and D2W bonding. In other embodiments, techniques including wire bonding and other forms of indirect bonding may be performed alone or in combination with W2W, D2D, and D2W bonding. In some embodiments, circuits may be bonded directly facing each other, while in other embodiments a flip-chip bonding may be used. In some embodiments, interconnections may be made between substrates on a front or circuit side of the substrate.

As used herein, conductors may refer to a variety of conductive materials, including which materials may be used alone or in combination with other materials such as in the form of an alloy. In some embodiments, the conductor is copper (Cu). In some embodiments, copper (Cu) may be in the form of Cu (II), Cu (III) or other forms of copper, alone or in combination with additional elements, including cobalt (Co) and ruthenium (Ru). Such a listing of elements is not intended to be exhaustive, and in other embodiments, any known other type of conductive material may be used.

As used herein, a device stack or stack of devices may refer to a combination of memory and supporting circuit architecture, for example, chiplets and dies containing individual memory elements, supporting processing units, input output (I/O) circuitry, and other forms of integrated chips. As used herein, a chiplet may refer to an integrated circuit having a well-defined functionality, such as a microprocessor, a memory device, or other computational function; with a chiplet enabling a modular design with multiple chiplets able to be combined with a larger package, sharing a substrate or interposer to form a larger device. A core may refer to a single unit of a multicore device where multiple devices form a larger device, with each device able to function independently to enable multiple streams of operations. In some embodiments, a core may take the form of a chiplet, or a chiplet may take the form of a core. However, in other embodiments, a chiplet may take the form of any other suitable integrated circuit.

Disclosed herein are various devices, structures and methods related to a package structure including both electronic integrated circuits, EICs, and photonic integrated circuits, or PICs, in the same package referred to herein as a hybrid package. In some embodiments, a package containing both EIC and PIC components may also be referred to using terms such as co-packaged optics (CPO), hybrid devices, or EPIC packaging. A base substrate such a silicon interposer may be used to form the base for the hybrid package for additional EICs and PICs. The base substrate may include interconnections to couple the components mounted upon the substrate to each other as well to a supporting substrate on a bottom side of the base substrate. The supporting substrate may be an organic substrate, a glass core substrate, a silicon substrate, or a substrate formed of any other suitable semiconductor material, as well as take the form of a printed circuit board, card, or interposer for use in a computer or server. The base substrate may have one or more processing units, such as one or more of CPUs, GPUs, XPUs, ASICs, or any other suitable processor, mounted upon a top surface and coupled to the base substrate. The base substrate may also include one or more monolithic optical engines mounted on the top side of the base substrate, including a first monolithic optical engine and a second monolithic optical engine.

The one or more monolithic optical engines may include a combination of electrical circuits and photonic circuits integrated together. The photonic circuits may include photonic elements such as waveguides, couplers, optical filters, phase shifters, polarizers, gratings, multiplexers, demultiplexers, lenses, mirrors, and optical ring resonators. The electrical circuits may include photodetectors such as photodiodes, amplifiers such as transimpedance amplifiers (TIAs), analog-to-digital converters (ADCs), digital-to-analog converters (DACs), comparators, electrical heaters, drivers, as well as routing and coupling layers such as TSVs, redistribution layers (RDLs), and coupling circuitry for power and communications signals. Upon each of the one or more monolithic optical engines one or more near compute devices may be formed, including a first near compute device and a second near compute device. The one or more near compute devices may include near compute devices such as memory devices or processing devices, as well as device stacks including combinations of processing devices and memory devices such as HBMs. The one or more near compute devices may be coupled with the base substrate via the monolithic optical engines, and in turn communicate with the one or more processing units. The one or more monolithic optical engines may include one or more optical couplers, which may take the form of one or more fiber attach units (FAUs). Each of the one or more monolithic optical engines may receive and transmit optical signals via the one or more bi-directional optical couplers and may convert optical signals to electrical signals for use by the one or more near compute devices or the one or more processing units.

In addition, the base substrate may include one or more PIC transceivers. The one or more PIC transceivers may provide one or more additional optical couplers, the one or more additional optical couplers receiving and/or transmitting optical signals to the hybrid package. The one or more PIC transceivers may include photonic elements such as waveguides, couplers, optical filters, phase shifters, gratings, multiplexers, demultiplexers, lenses, mirrors, and optical ring resonators to route optical signals. The one or more PIC transceivers may include supporting electrical circuitry such as photodetectors, drivers, amplifiers, etc. integrated into the one or more PIC transceivers, or may have some or all of the elements on a supporting EIC to provide control and monitoring for the one or more PIC transceivers. The one or more PIC transceivers may be coupled via the base substrate to the one or more optical engines and the one or more processing units.

The one or more monolithic optical engines may have multiple internal communication pathways, enabling optical communications to be routed directly to either the one or more near compute devices or the one or more processing units, as well as enabling direct electrical communication between the one or more near compute devices and the one or more processing units. For example, one or more physical layers may be provide on one of the one or more monolithic optical engines, the one or more physical layers providing coupling between the one or more monolithic optical engines and the one or more near compute devices, and the one or more processing units.

The hybrid package may have multiple external communication pathways, enabling optical communications between one or more adjacent hybrid packages as well as between the hybrid package and one or more optical switches. In some embodiments, a first hybrid package may optically communicate via the first monolithic optical engine to a second hybrid package, while the first hybrid package may also optically communicate via a first PIC transceiver to an optical switch. In some embodiments, hybrid packages may communicate directly via the one or more monolithic optical engines such that signals may be routed directly between near compute devices on adjacent hybrid packages, directly between processing units on adjacent hybrid devices, or between near compute devices and processing units on adjacent hybrid packages. Direct optical connections between hybrid packages may allow for multiple hybrid packages to pool their computing power.

As the hybrid package may communicate bi-directionally at each monolithic optical engine, as well as at the one or more PIC transceivers, the communications bandwidth for each hybrid package may be increased. Additionally, as each monolithic optical engine may support one or more near compute devices, the memory capacity of each hybrid package may be increased. As such, a hybrid package as disclosed herein may increase the memory capacity and increase the optical bandwidth simultaneously and without a trade-off. The disclosed hybrid packages may be useful, for example, high-powered computing uses such as AI.

The disclosed hybrid packages may be assembled by first assembling each monolithic optical engine and each near compute device, including forming the electrical and photonic components on each monolithic optical engine. The near compute devices may then be mounted on their respective monolithic optical engines including coupling the physical interface between the near compute devices and respective monolithic optical engine, including forming conductive connections to electrically couple the monolithic optical engines and near compute devices. The optical connections may then be mounted on their respective monolithic optical engine and coupled using an adhesive such as an epoxy to the optical pathways of the monolithic optical engines. The base substrate is prepared, including forming any redistribution layers, through-vias, and supporting elements such as logic, routing, or power distribution elements within the base substrate. The monolithic optical engines, processing units, and PIC transceivers may then be mounted on the base substrate, including the formation of conductive couplings to provide power and electrical communication signals between the package components and the base substrate. Additionally, dielectric couplings may be formed between the package components, such as by using an underfill method to insert an adhesive or epoxy between conductive connections. The hybrid packages may further be encased by a molding material, such as an epoxy molding compound, with the molding material able to fill spaces between each of the package components, as well as able to encapsulate exposed surfaces of the base substrate. The molding material may cover the top surfaces of the package components, or at least portions of the top surfaces of the package components may be exposed. For example, the optical connections may have an exposed surface to enable coupling with an optical fiber. In some embodiments, a lid formed of a heat conductive material such as a ceramic like glass or silicon dioxide, or silicon wafers, or a metal material such as aluminum, or copper, may be placed over the molding layer and provide a heat transfer surface for the hybrid package.

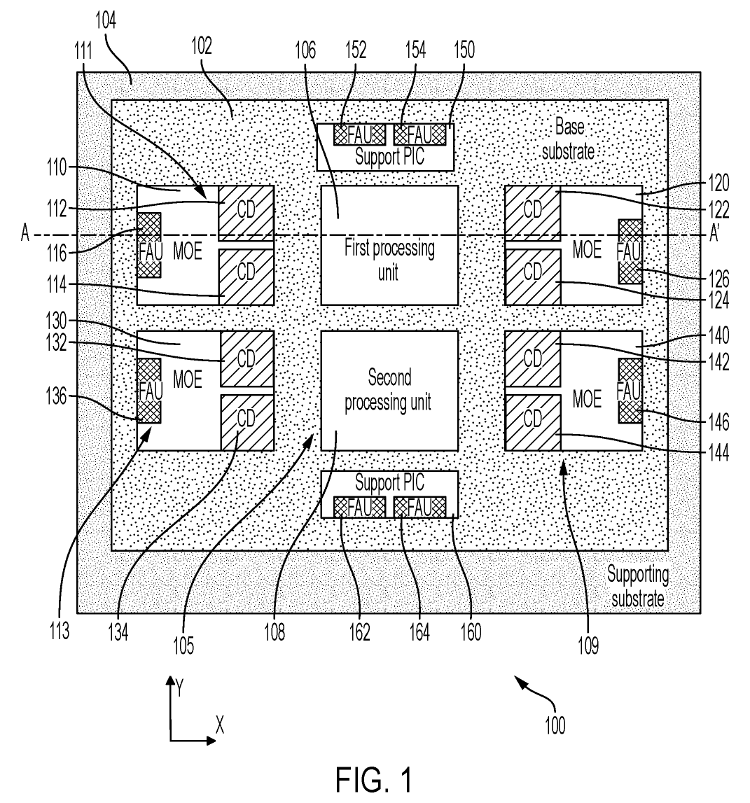

FIG. 1 depicts a cross-sectional view of an example embodiment of a first device package architecture 100 formed on a base substrate 102. The base substrate may take the form of a semiconductor substrate, such as a silicon substrate. The base substrate 102 may in turn be supported by a supporting substrate 104. In some embodiments, the supporting substrate 104 may include an organic substrate such as a polymer, a glass substrate, a glass core substrate, a silicon substrate, or another other suitable substrate, while in other embodiments the supporting substrate 104 may take the form of an interposer, a circuit board, a card or other structure providing electrical signals and routing to the first device package architecture 100.

One or more processing units 105 may be formed on top of the base substrate 102. In the example of FIG. 1, the one or more processing units 105 may include a first processing unit 106 and a second processing unit 108, while in other embodiments, one, three, four or more processing units may be included in the one or more processing units 105. The one or more processing units 105 may take the form of a suitable processing device including CPU, XPU, GPUs, as well as additional supporting circuitry and combinations thereof. The one or more processing units 105 may be coupled via the base substrate 102 to additional circuitry on the base substrate 102 and to the supporting substrate 104 with both communications signals and power.

One or more monolithic optical engines 109 may be formed on top of the base substrate 102. The one or more monolithic optical engines 109 may also be referred to as MOEs. In the example of FIG. 1, the one or more monolithic optical engines 109 may include a first monolithic optical engine 110, a second monolithic optical engine 120, a third monolithic optical engine 130, and a fourth monolithic optical engine 140. However, the number of the one or more monolithic optical engines 109 may vary, and in other embodiments may be two, six, eight or more.

The one or more monolithic optical engines 109 may take the form of one or more layers of optical components upon an optical substrate, for example glass, polymer, and silicon oxide. In some embodiments, one or more buried oxide layers or BOX layers may be formed upon an optical substrate and contain various photonic device components. The one or more monolithic optical engines 109, may, in some embodiments, include components for modulating the optical signals such as micro-ring resonators, serializers, phase shifters, couplers, lenses, polarizers, gratings, anti-reflection coatings, optical filters, index matching coatings, mirrors, delay lines, and a variety of other photonic elements both passive and active. An optical signal may, in some embodiments, be generated from an external source and provided to the one or more monolithic optical engines 109, while in other embodiments, the one or more monolithic optical engines 109 may include a light generation source such as a laser source such as a laser diode, a four-wave-mixing-based frequency comb, a Kerr frequency comb, or any other suitable technique for generating an optical signal. In some embodiments, a comb signal having a plurality of wavelengths separated into discrete spectra may be used. The photonic components of the one or more monolithic optical engines 109 may modulate, redirect, combine, separate and otherwise modify an optical signal within the one or more monolithic optical engines 109.

Additionally, the one or more monolithic optical engines 109 may include one or more layers of electrical components. In some embodiments, the one or more monolithic optical engines 109 may include the driving electronics for the photonic components on the one or more monolithic optical engines 109, including heater control circuits, heater drivers, modulator drivers, and serializers to modify the optical signal within the one or more monolithic optical engines 109. For example, if the one or more monolithic optical engines 109 includes one or more micro-ring resonators, heaters may be integrated with the one or more micro-ring resonators to provide control over the resonance frequency of the one or more micro-ring resonators by altering the physical characteristics of the one or more micro-ring resonators. While portions of the heaters may be formed within the one or more monolithic optical engines 109, the electronics controlling and regulating the heater may be formed separately on the one or more monolithic optical engines 109. Furthermore, the one or more monolithic optical engines 109 may include one or more photodetectors to receive an optical signal, which may be subject to further signal processing, including amplification, analog-to-digital conversion, rectification, or any other suitable signal processing techniques. In some embodiments, some or all of the driving electronics for the one or more monolithic optical engines 109 may be transferred to another device, such as an additional EIC which may connect directly to the base substrate 102, or via the supporting substrate 104.

The one or more monolithic optical engines 109 may include additional electronic circuitry, such as a logic structure for routing electrical signals from the one or more monolithic optical engines 109 to the rest of the first device package architecture 100. In some embodiments, one or more redistribution layers or RDL may be formed on or within the one or more monolithic optical engines 109 and provide one or more layers including a series of pads, bumps, vias, through-vias, traces, and other forms of connection for redistributing signals. In some embodiments, one or more through-substrate vias or TSVs may couple between a top and bottom side of the one or more monolithic optical engines 109.

On the one or more monolithic optical engines 109, one or more near compute devices 111 may be formed. The one or more near compute devices 111 may be referred to in some embodiments as a CD. In the example of FIG. 1, the one or more near compute devices 111 may include a first near compute device 112 and a second near compute device 114 on the first monolithic optical engine 110, a third near compute device 122 and a fourth near compute device 124 on the second monolithic optical engine 120, a fifth near compute device 132 and a sixth near compute device 134 on the third monolithic optical engine 130, and a seventh near compute device 142 and an eighth near compute device 144 on the fourth monolithic optical engine 140. The one or more near compute devices 111 may take the form of one or more component devices such as memory devices including DRAM, SRAM, and other forms of memory; processing devices such as CPUs, XPUs, ASICs, and stacks of component devices including combinations of memory and processing devices such as HBMs. In some embodiments, the stack of component devices may include one or more memory devices, core devices, and combinations thereof, for example HBM may include a core processing device with additional memory devices stacked upon the core processor.

The one or more near compute devices 111 may be mounted on the one or more monolithic optical engines 109 in a variety of ways and may include pads, bumps, microbumps, pillars, balls, ball grids, microball arrays, and other forms such as controlled-collapse chip connection (C4) bumps, alone or in combination. As used herein, a C4 bump refers to a form of solder bumps placed on pads on a top surface of a substrate prior to flipping the substrate to form a flip-chip. The mounting method may further include a dielectric material, which may include a material such as an adhesive, resin, or elastomer which may form a connection in addition to a conductive connection. In some embodiments, the combination of a conductive connection and a dielectric connection may form a hybrid bond where both a dielectric bond is formed between dielectric surfaces and a conductive bond is formed between conductive surfaces on opposing faces. In some embodiments, the one or more monolithic optical engines 109 may have one or more RDL formed to include pads and vias to couple to the base substrate 102 to provide both communication signals and power.

On the one or more monolithic optical engines 109, one or more optical connections 113 may be formed. In the example of FIG. 1, the one or more optical connections 113 may include a first optical connection 116 on the first monolithic optical engine 110, a second optical connections 126 on the second monolithic optical engine 120, a third optical connection 136 on the third monolithic optical engine 130, and a fourth optical connection 146 on the fourth monolithic optical engine 140.The one or more optical connections 113, which may be referred to also as an FAU, may include an optical connector, an optical fiber, a FAU, a pluggable optical connector, a plug connector, a v-groove, as well as combinations thereof and various arrays thereof. The one or more optical connections 113 may optically couple to one or more bi-directional fibers to transmit and receive optical signals to and from each of the one or more monolithic optical engines 109. The one or more monolithic optical engines 109 may then transmit received signals to the one or more near compute devices 111 as well as the one or more processing units 105. In some embodiments, the one or more monolithic optical engines 109 may transmit received signals directly to the one or more near compute devices 111, while in other embodiments, the one or more monolithic optical engines 109 may transmit received signals directly to the one or more processing units 105. Additionally, the one or more monolithic optical engines 109 may transmit via the one or more optical connections 113 from signals received from the one or more near compute devices 111 or the one or more processing units 105.

Furthermore, one or more support PICs may be formed on top of the base substrate 102. In the examples provided, the one or more support PICs take the form of a first support PIC 150 and a second support PIC 160, but in other embodiments, the number of the one or more support PIC may be one, three, four or more. The one or more support PIC may be formed similarly to the one or more monolithic optical engines 109, and may include auxiliary optical couplers, such as a first auxiliary optical coupler 152 and a second auxiliary optical coupler 154 on the first support PIC 150 and a third auxiliary optical coupler 162 and a fourth auxiliary optical coupler 164 on the second support PIC 160. The auxiliary optical couplers may take the same form as the one or more optical connections 113 on the one or more monolithic optical engines 109, such as a FAU. The auxiliary optical couplers may be either unidirectional or bidirectional couplers and may each couple in turn to a separate optical fiber. Signals from the one or more support PICs may be coupled via the base substrate 102 to the one or more processing units 105. Additionally, the one or more support PICs may have some or all of the supporting electronics formed upon the one or more support PICs or may have a portion or more of the supporting electronics formed in a separate EIC device coupled to the one or more support PICs.

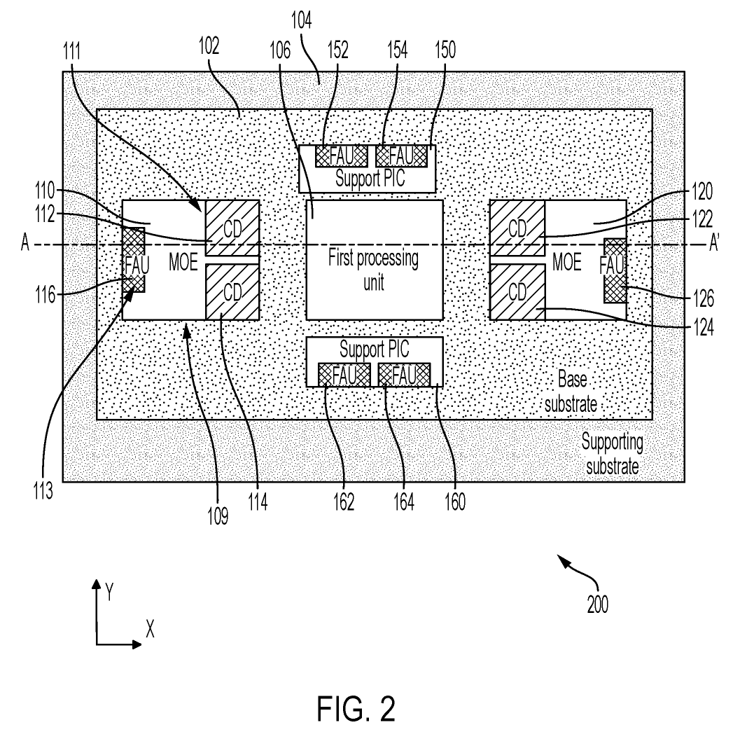

FIG. 2 depicts a second device package architecture 200, the second device package architecture 200 differing from the first device package architecture 100 of FIG. 1 by having only a single processing unit, the first processing unit 106, and only two monolithic optical engines, the first monolithic optical engine 110 and the second monolithic optical engine 120. However, the second device package architecture 200 still may include the first support PIC 150 and the second support PIC 160.

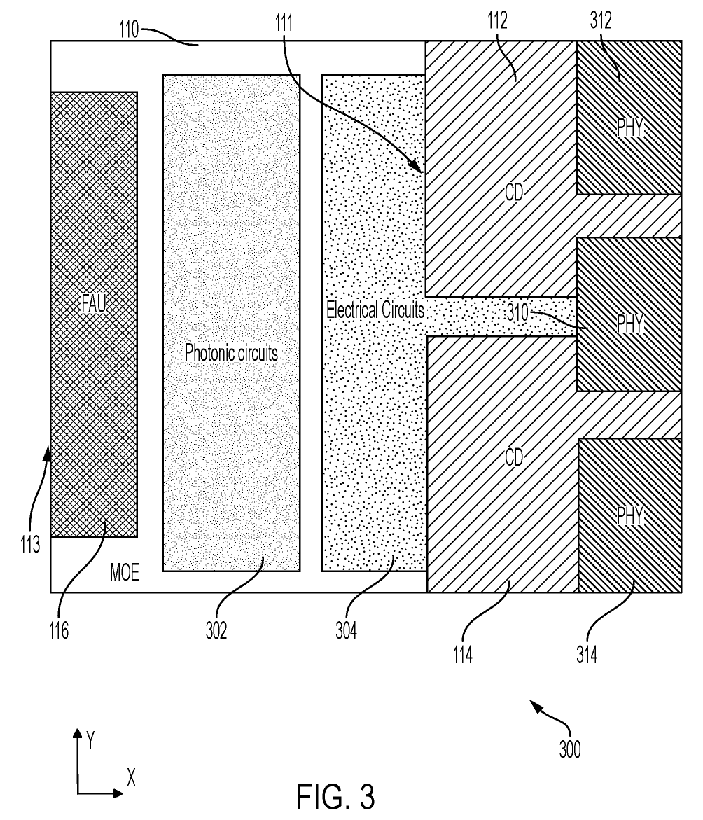

FIG. 3 depicts an enlarged view 300 of the first monolithic optical engine 110, showing the first monolithic optical engine 110 in more detail than in FIG. 1. Although FIG. 3 will discuss the first monolithic optical engine 110, each of the one or more monolithic optical engines 109 may be formed similarly. The first monolithic optical engine 110 may include the first optical connection 116 on a side distal from the first processing unit 106. The first optical connection 116 may be formed, in some embodiments, on a side to allow an optical fiber to more easily reach the first monolithic optical engine 110, while in other embodiments the first optical connection 116 may be formed on top of the first monolithic optical engine 110. The first near compute device 112 and the second near compute device 114 may be formed on a side proximal to the first processing unit 106. Proximal to the first optical connection 116, one or more photonic circuits 302 may be formed. The one or more photonic circuits 302 may include components for modulating optical signals such as micro-ring resonators, serializers, phase shifters, couplers, lenses, polarizers, gratings, anti-reflection coatings, optical filters, index matching coatings, mirrors, delay lines, and a variety of other photonic elements both passive and active. The one or more photonic circuits 302 may allow for both transmitting and receiving optical signals. Proximal to the first near compute device 112 and the second near compute device 114, one or more electrical circuits 304 may be formed. The one or more electrical circuits 304 may include electrical components to control the one or more photonic circuits 302, such as drivers, as well as components such as amplifiers for receiving and transmitting signals via the one or more photonic circuits 302.

A first physical interface 312 may be formed on the first monolithic optical engine 110 to couple the first near compute device 112 to the first monolithic optical engine 110 and to the first processing unit 106. A second physical interface 314 may be formed on the first monolithic optical engine 110 to couple the second near compute device 114 to the first monolithic optical engine 110 and to the first processing unit 106. A central physical interface 310 may be formed on the first monolithic optical engine 110 to couple the one or more electrical circuits 304 to the first near compute device 112, the second near compute device 114 and to the first processing unit 106. In some embodiments, the arrangement of the physical interfaces may be such that each of the first physical interface 312, the second physical interface 314 and the central physical interface 310 to a corresponding physical interface on the first processing unit 106. For example, the first processing unit 106 may have a shoreline providing corresponding physical interfaces allowing for D2D communication from the first processing unit 106 to the first near compute device 112, the first processing unit 106 to the second near compute device 114, and the first processing unit 106 and the first monolithic optical engine 110.

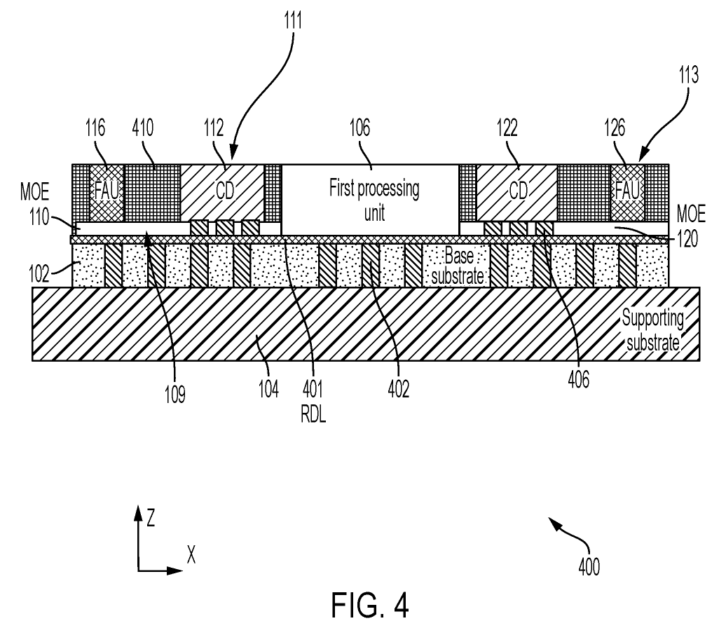

FIG. 4 depicts a cross-sectional view 400 of the first device package architecture 100 or the second device package architecture 200. In the cross-sectional view 400, a redistribution layer 401 is provided on the surface of the base substrate 102 and couples to one or more pillars 402 in the base substrate 102. The redistribution layer 401 may provide one or more layers including a series of pads, bumps, vias, through-vias, traces, and other forms of connection for redistributing signals from connections from the supporting substrate 104 to the one or more pillars 402, the first processing unit 106, the first monolithic optical engine 110, the first near compute device 112, the second monolithic optical engine 120, and the third near compute device 122. In some embodiments, one or more layers of the redistribution layer 401 may be formed on top of the base substrate 102, within the base substrate 102, or on the bottom of the base substrate 102 and adjacent to the supporting substrate 104. The redistribution layer 401 may provide both power and communicative coupling between connected devices.

An interconnection formed between the base substrate 102 and the supporting substrate 104 may include conductive materials to couple the base substrate 102 to the supporting substrate 104 including pads, bumps, microbumps, pillars, balls, and other forms such as C4 bumps, alone or in combination. In some embodiments, a bonding layer between the base substrate 102 and the supporting substrate 104 may include a dielectric material or an adhesive, like underfill material, to provide additional strength and connection between the base substrate 102 and the supporting substrate 104. In some embodiments, the interconnection may provide a metallic bonding between the base substrate 102 and the supporting substrate 104, a dielectric bonding between the base substrate 102 and the supporting substrate 104, or in some embodiments, a hybrid bonding between the base substrate 102 and the supporting substrate 104. In some embodiments, the interconnection may bond directly with the redistribution layer 401, while in other embodiments, intermediate layers may be between the interconnection and the redistribution layer.

The first monolithic optical engine 110 and the second monolithic optical engine 120 may be mounted directly on the redistribution layer 401 or may have one or more intermediate layers between, for example, to provide additional routing, logic, and power management, as well as may include a bonding layer such as an adhesive or dielectric underfill to bond the one or more monolithic optical engines 109 to base substrate 102. The one or more monolithic optical engines 109 may each include one or more TSV 406 to couple the one or more near compute devices 111 to the redistribution layer 401 and the one or more processing devices. The one or more

A molding layer 410 may be formed over the one or more monolithic optical engines 109 and the one or more processing units 105. The molding layer 410 may be formed from a dielectric material such as silicon dioxide, resins, adhesives, and epoxies, alone or in combination, and may, in some embodiments, include an epoxy molding compound (EMC). The molding layer 410 may be formed between adjacent elements on the one or more monolithic optical engines 109 such as the first near compute device 112 and the first optical connection 116. The molding layer 410 may provide physical, thermal, and/or electrical protection for the elements mounted on a hybrid package as disclosed herein. The molding layer 410 may secure the various components in place, while providing protection from both physical and electrical shock, and ensuring optical fibers stay aligned. The molding layer 410 may be formed to create a planar upper surface as shown in the cross-sectional view 400. In some embodiments, one or more of the components such as the one or more processing units 105 and the one or more near compute devices 111 may be covered in whole or in part by the molding layer 410 to form a planar surface, while in other embodiments, the molding layer 410 may expose the one or more components.

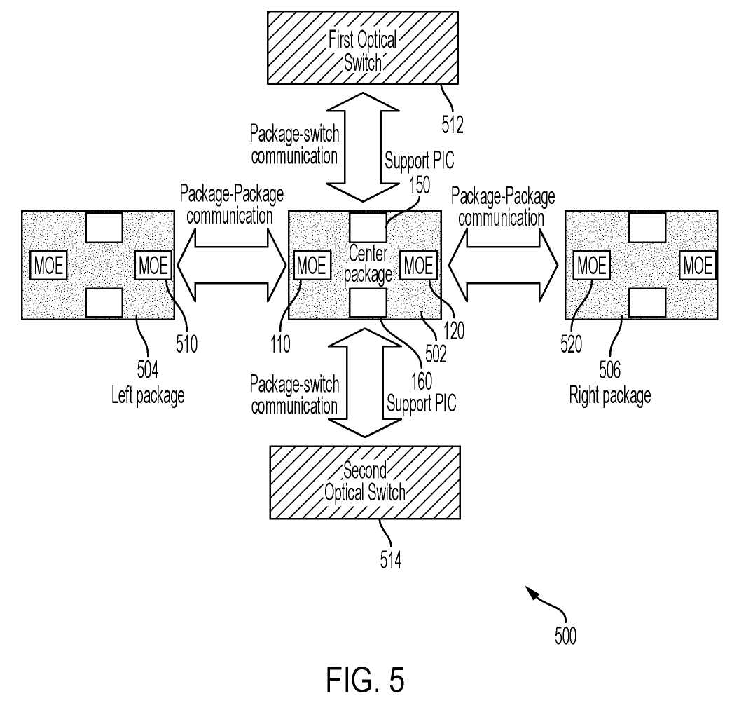

FIG. 5 depicts an example of a first communication arrangement 500 for a central hybrid package 502. The central hybrid package 502 may take the form of any hybrid package disclosed herein, including the first device package architecture 100 and the second device package architecture 200. In the example of FIG. 5, the central hybrid package 502 may be optically coupled via the first monolithic optical engine 110 to a first adjacent hybrid package 504 with a first adjacent monolithic optical engine 510. The central hybrid package 502 may have the second monolithic optical engine 120 similarly optically coupled to a second adjacent hybrid package 506 via a second adjacent monolithic optical engine 520. One or more optical fibers may provide bi-directional communication between the central hybrid package 502 and the first adjacent hybrid package 504 as well as the second adjacent hybrid package 506. As the hybrid packages are coupled via the monolithic optical engines, signals may be routed between the corresponding processing units, between the near compute devices, or combination thereof. The first support PIC 150 and the second support PIC 160 on the central hybrid package 502 may in turn be optically coupled to a corresponding switch of a first optical switch 512 and a second optical switch 514. The optical switches may act as network switching modules, and in some embodiments, provide inter-racks communication within a datacenter. In contrast, the hybrid packages may communicate directly between each other and provide intra-rack communication.

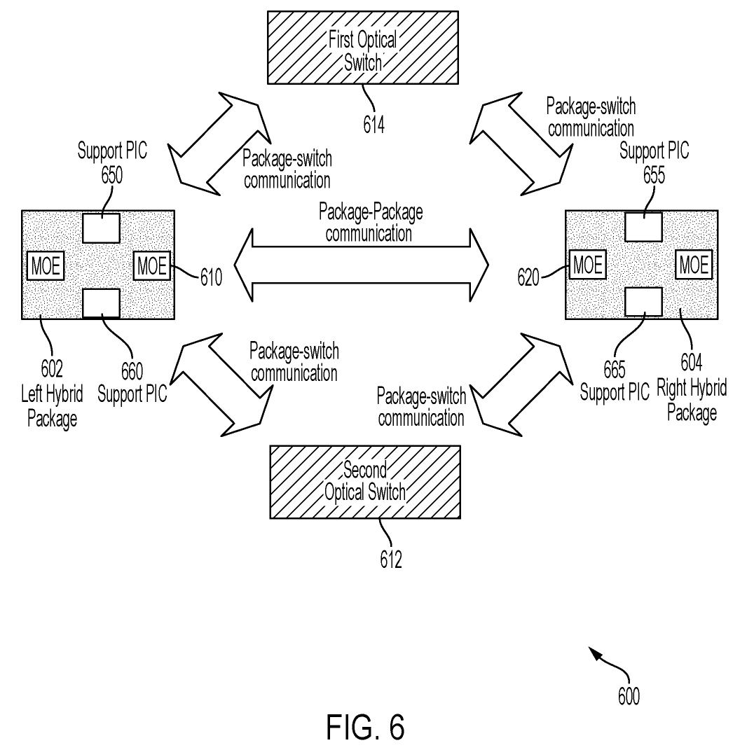

FIG. 6 depicts an example of a second communication arrangement 600, differing from the first communication arrangement 500 by demonstrating multi-package communication from a left hybrid package 602 and a right hybrid package 604 to a first switch 612 and a second switch 614. The left hybrid package 602 and the right hybrid package 604 may take the form of any hybrid package disclosed herein, including the first device package architecture 100 and the second device package architecture 200. In the example of FIG. 6, the left hybrid package 602 may be optically coupled via the first left monolithic optical engine 610 to a first right monolithic optical engine 620 to the right hybrid package 604. One or more optical fibers may provide bi-directional communication between the left hybrid package 602 and the right hybrid package 604. As the hybrid packages are coupled via the monolithic optical engines, signals may be routed between the corresponding processing units, between the near compute devices, or combination thereof. The first left support PIC 650 and the second left support PIC 660 on the left hybrid package 602 may in turn be optically coupled to the first switch 612 and the second switch 614. The first right support PIC 655 and the second right support PIC 665 on the right hybrid package 604 may in turn be optically coupled to the first switch 612 and the second switch 614. The optical switches may act as network switching modules, and in some embodiments, provide inter-racks communication within a datacenter. In contrast, the hybrid packages may communicate directly between each other and provide intra-rack communication.

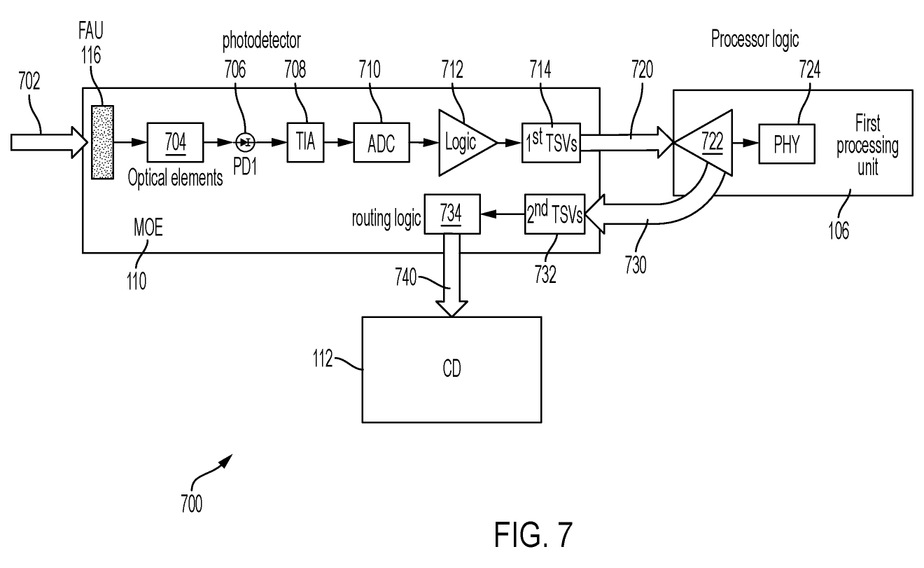

FIG. 7 depicts an example embodiment of a first data communications path 700 demonstrating a signal received between adjacent hybrid modules such as the left hybrid package 602 and the right hybrid package 604 in FIG. 6. On the first monolithic optical engine 110, an incoming optical signal 702 is received by the first optical connection 116, for example, from an incoming optical fiber. The incoming optical signal 702 is then transmitted to one or more photonic elements 704, which may include optical filters, gratings, phase shifters, waveguides, splitters, multiplexers, etc. The one or more photonic elements 704 may provide routing and logic for the incoming optical signal 702, such as splitting a multiplexed signal into individual optical signals. At one or more photodetectors 706, the incoming optical signal 702 is converted to an electrical signal. The one or more photodetectors 706 may take the form of an optical sensor, such as photodiodes, photomultiplier tubes, charge-coupled devices (CCDs), or any other appropriate optical sensor. Signals from the one or more photodetectors 706 may be fed to one or more amplifiers 708, which may take the form of a transimpedance amplifier or TIA, to produce amplified signals. The amplified signals from the one or more amplifiers 708 may then be fed to one or more ADC 710 to convert the amplified analogue signals into digital signals. The digital signals from the one or more ADC 710 may be combined at a logic circuit 712. The combined digital signals 720 are then transmitted via one or more first TSVs 714 from the first monolithic optical engine 110 to the base substrate 102 and on to the first processing unit 106. The processing logic 722 may then route the signals via a physical layer 724 of the first processing unit 106. The first processing unit 106 may then read the combined digital signals 720 and provide a write signal 730 for transmission to the first near compute device 112. The write signal 730 may transmit back via the processing logic 722 and via the base substrate 102 to the first monolithic optical engine 110. The write signal 730 may be transmitted in the first monolithic optical engine 110 via one or more second TSVs 732 to first near compute device routing logic 734, which may take the form of the first physical interface 312. Then via the first near compute device routing logic 734, the write signal 730 may reach the first near compute device 112 as received signal 740. In the first data communications path 700, incoming signals are routed first to the one or more processing units 105, then to the one or more near compute devices 111.

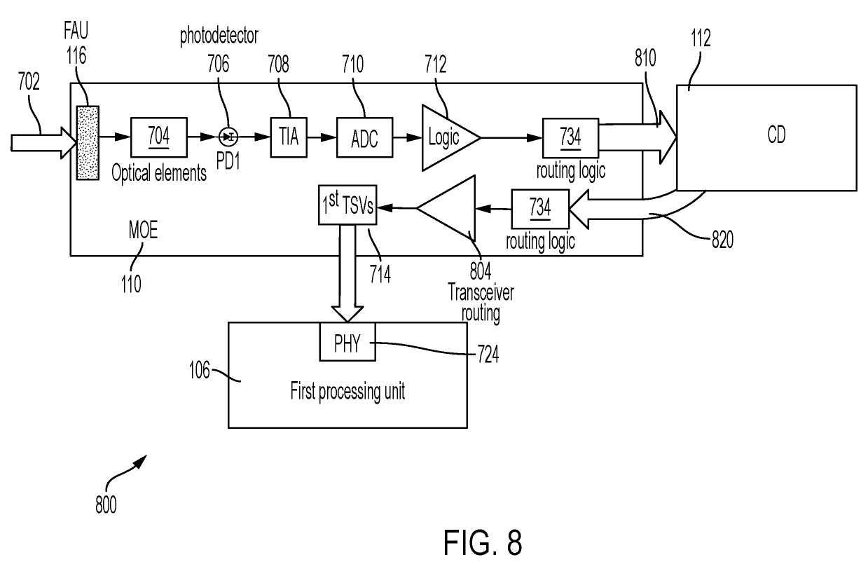

FIG. 8 depicts an example embodiment of a second data communications path 800 demonstrating a received transmitted between adjacent hybrid modules such as the left hybrid package 602 and the right hybrid package 604 in FIG. 6. The second data communications path 800 differs from the first data communications path 700 by routing signals to the one or more near compute devices 111 prior to the one or more processing units 105. As the one or more near compute devices 111 may include memory and take the form of HBM, data transmitted between adjacent packages may be stored directly in the one or more near compute devices 111 and off load the computational burden from the one or more processing units 105. The second data communications path 800 may be initially the same and diverge after the combined digital signals are produced by the logic circuit 712, a write signal 810 may be routed via the first near compute device routing logic 734 to the first near compute device 112. A read signal 820 may be produced by the first near compute device 112 and transmitted back to the first monolithic optical engine 110 via the first near compute device routing logic 734, and before being provided to the transceiver logic circuit 804 to route the signal. The read signal 820 may be then routed via the one or more first TSVs 714 and transmitted via the base substrate 102 to the first processing unit 106 and received by the physical layer 724.

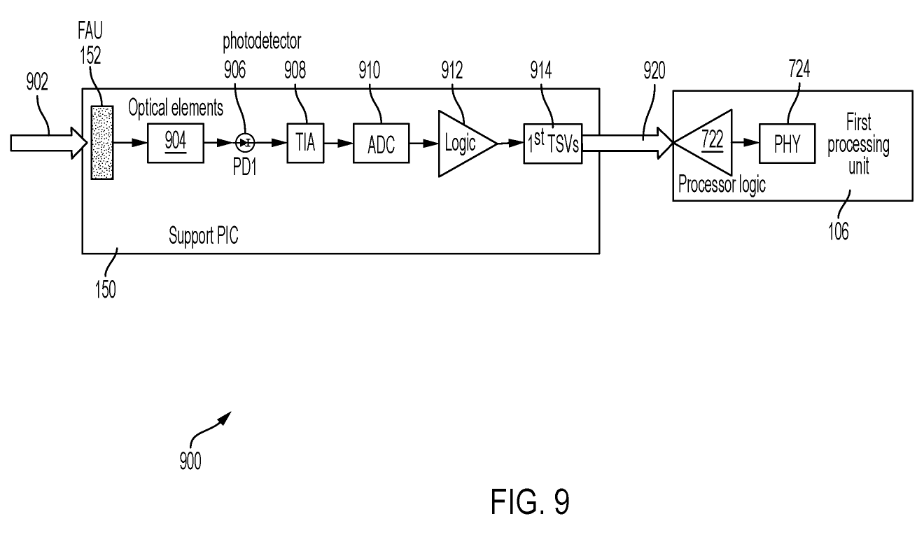

FIG. 9 depicts an example embodiment of a third data communications path 900 demonstrating an incoming optical signal 902 received by one of the one or more support PIC such as the first support PIC 150. The routing of the first support PIC 150 may be largely similar to incoming communications on the one or more monolithic optical engines 109. The incoming optical signal 902 is received by the first auxiliary optical coupler 152, for example, from an incoming optical fiber. The incoming optical signal 902 is then transmitted to one or more supporting photonic elements 904, which may include optical filters, gratings, phase shifters, waveguides, splitters, multiplexers, etc. The one or more supporting photonic elements 904 may provide routing and logic for the incoming optical signal 902, such as splitting a multiplexed signal into individual optical signals. At one or more supporting photodetectors 906, the incoming optical signal 902 is converted to an electrical signal. The one or more supporting photodetectors 906 may take the form of an optical sensor, such as photodiodes, photomultiplier tubes, charge-coupled devices (CCDs), or any other appropriate optical sensor. Signals from the one or more supporting photodetectors 906 may be fed to one or more supporting amplifiers 908, which may take the form of a transimpedance amplifier or TIA, to produce amplified signals. The amplified signals from the one or more supporting amplifiers 908 may then be fed to one or more supporting ADC 910 to convert the amplified analogue signals into digital signals. The digital signals from the one or more supporting ADC 910 may be combined at a supporting logic circuit 912. The combined supporting digital signals 920 are then transmitted via one or more first supporting TSVs 914 from the first support PIC 150 to the base substrate 102 and on to the first processing unit 106. The processing logic 722 may then route the signals via a physical layer 724 of the first processing unit 106. The first processing unit 106 may then read the combined digital signals 720 and provide write signals to the near compute devices as discussed above with respect to FIG. 7.

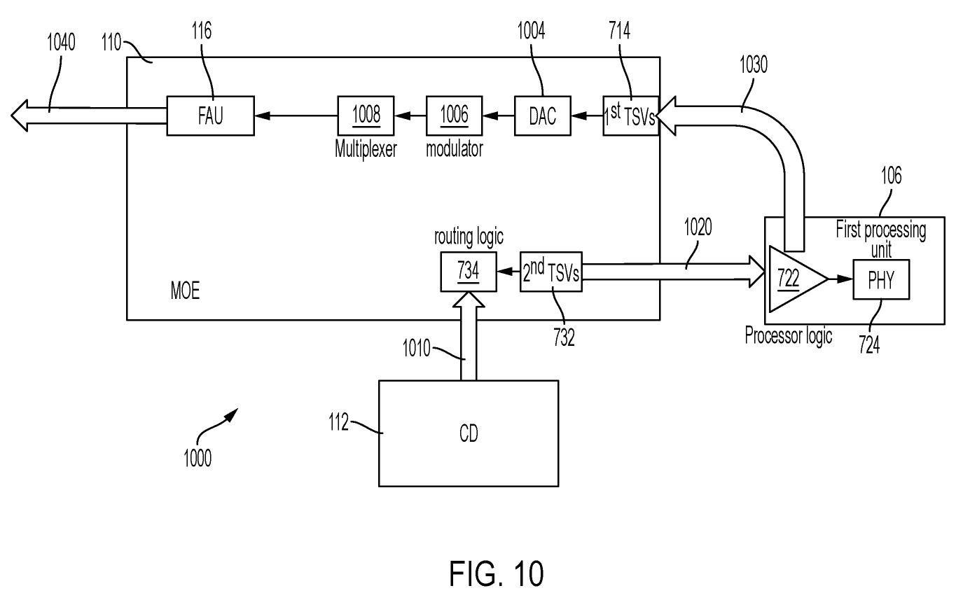

FIG. 10 depicts an example embodiment of a fourth data communications path 1000 demonstrating a signal 1010 transmitted between adjacent hybrid modules such as the left hybrid package 602 and the right hybrid package 604 in FIG. 6. The fourth data communications path 1000 differs from the first data communications path 700 and the second data communications path 800 by providing the transmission path from a hybrid package. A read signal 1020 from the first near compute device 112 is transmitted via the first near compute device routing logic 734 to the one or more second TSVs 732, to the base substrate 102 and provided to the processing logic 722 of the first processing unit 106 which may then route the signals via the physical layer 724. The first processing unit 106 then provides an outgoing signal 1030, which may be transmitted via the processing logic 722 to the base substrate 102 and to the first monolithic optical engine 110 at the one or more first TSV 714. The outgoing signal 1030 may then be converted from digital to analogue at one or more DAC 1004. The analogue signals may be used to control a modulator 1006, which receives a base optical signal. The base optical signal may be generated by a light source, such as a laser diode, or a comb frequency source, and as necessary demultiplexed by wavelength, mode and polarization into one or more optical signals. The modulator 1006 may then take the analogue electric signal provided by the one or more DAC 1004 and produce an outgoing optical signal. One or more outgoing optical signals may then be combined at an optical multiplexer 1008 to produce a combined optical signal 1040, which the first optical connection 116 may transmit via an optical fiber to another hybrid package. In some embodiments, additional optical routing may be further performed, which may have additional driving signals, for example on heaters to control the optical pathway.

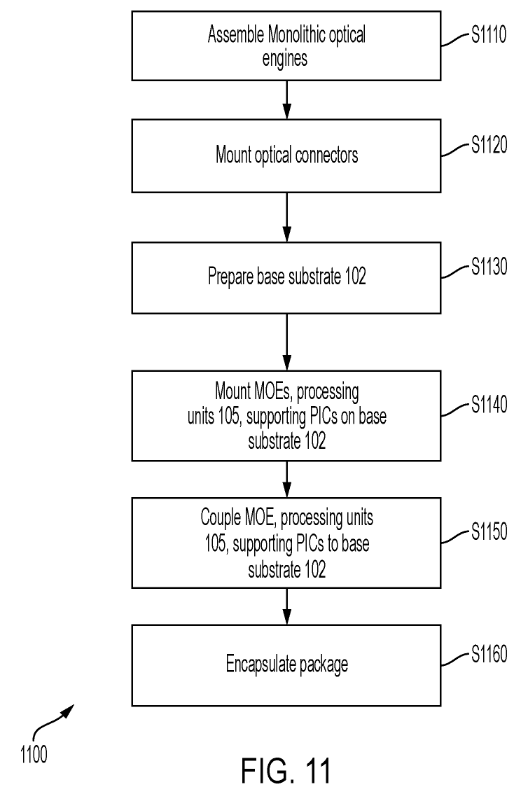

FIG. 11 depicts an example embodiment of a process 1100 for assembling a cooling architecture such as the first device package architecture 100 or any other device package architecture shown in FIGS. 1-10.

In the process 1100 at S1110, the one or more monolithic optical engines 109 are prepared. The one or more monolithic optical engines 109 may be assembled in a front end of line (FEOL) or back end of line (BEOL) facility, as well as a combination thereof. For example, the one or more near compute devices 111 may consist of one or more components devices such as a memory device like DRAM, SRAM, and other forms of memory, as well as processing devices such as a CPU or microprocessor, which are combined to form a near compute device such as HBM. The component devices of the one or more near compute devices 111 may be each formed in separate FEOL facilities, and combined together in a BEOL facility to form a stacked device. Similarly, portions of the one or more monolithic optical engines 109 may be formed in a FEOL facility to create the various photonic and electronic circuit elements present in the one or more monolithic optical engines 109, while other elements may be added during a BEOL process. For example, at least a portion the driving electronics for the photonic components on the one or more monolithic optical engines 109, including heater control circuits, heater drivers, modulator drivers, and serializers to modify the optical signal within the one or more monolithic optical engines 109 may, in some embodiments, be formed directly on or within a layer of the one or more monolithic optical engines 109. In other embodiments, at least a portion of the driving electronics may be formed as part of a separate EIC and mounted directly on the one or more monolithic optical engines 109, or be transferred to the one or more monolithic optical engines 109 using various substrate transfer methods.

The one or more near compute devices 111 may then be assembled on the one or more monolithic optical engines 109 in a BEOL facility. The one or more near compute devices 111 may be mounted using various techniques including a conductive connection such as pads, bumps, microbumps, pillars, balls, ball grids, microball arrays, and other forms such as C4 bumps, alone or in combination. In some embodiments, the one or more near compute devices 111 may be mounted directly on the one or more monolithic optical engines 109, while in other embodiments one or more intermediate layers may be formed between the one or more monolithic optical engines 109 and the one or more near compute devices 111, such as a redistribution layer, interposer, logic circuit, or any other suitable intermediate. The mounting method may further include a dielectric material, which may include a material such as an adhesive, resin, epoxy, or elastomer which may form a connection in addition to a conductive connection and may be provided using an underfill method. In some embodiments, the one or more near compute devices 111 may be further secured using an epoxy molding compound or other suitable techniques to encapsulate the one or more near compute devices 111. When an underfill or epoxy molding compound is used as part of the mounting process, the one or more monolithic optical engines 109 may be subject to various processes to cure the epoxy or other adhesives used. In some embodiments, the curing may include thermal curing such as applying thermal energy such as a heater, as well as optical curing such as using a light source, as well as combinations thereof, as well as any other suitable curing method.

In the process 1100 at S1120, the one or more optical connections 113 may be mounted on the one or more monolithic optical engines 109. The one or more optical connections 113 may include an optical connector, an optical fiber, a FAU, a pluggable optical connector, a plug connector, a v-groove, as well as combinations thereof and various arrays thereof. In some embodiments, the one or more optical connections 113 may be formed directly on the one or more monolithic optical engines 109, while in other embodiments, the one or more optical connections 113 may be formed separately and mounted on the one or more monolithic optical engines 109. The one or more optical connections 113 may be mounted either on a top or side surface of the one or more monolithic optical engines 109, depending on the desired orientation of the optical fibers connecting to the one or more monolithic optical engines 109. The one or more optical connections 113 are mounted such that an optical signal may transmit between the one or more optical connections 113 and the optical pathways of the one or more monolithic optical engines 109. In some embodiments, the one or more optical connections 113 may include one or more intermediate components coupled between either the one or more optical connections 113 and an attached optical fiber or the one or more monolithic optical engines 109, such as lens, coupling devices, plugs, optical demultiplexers, optical multiplexers, filters, polarizers or other suitable intermediates. The one or more optical connections 113 may be mounted to the one or more monolithic optical engines 109 using various methods, for example including a pick and place machine to place the one or more optical connections 113 in the correct position. The one or more optical connections 113 may be coupled to the one or more monolithic optical engines 109 using an adhesive, an epoxy, elastomer, or other suitable compound, as well as using mechanical interconnections such as press fits, or any other suitable method. In some embodiments, an epoxy or other adhesive may be applied to the one or more monolithic optical engines 109 prior to mounting the one or more optical connections 113, while in other embodiments a process such as underfilling may be used to apply an adhesive or epoxy after mounting. The one or more optical connections 113 may be subject to various processes to cure the epoxy or other adhesives used. In some embodiments, the curing may include thermal curing such as applying thermal energy such as a heater, as well as optical curing such as using a light source, as well as combinations thereof, as well as any other suitable curing method.

In the process 1100 at S1130, the base substrate 102 is prepared to receive the other components. The base substrate 102 may be subject to a variety of methods to produce the necessary interconnections, including through-vias and one or more redistribution layers 401 including a series of pads, bumps, vias, through-vias, traces, and other forms of connection for redistributing signals. The base substrate 102 may thus be subject to a number of processes to form the necessary through-vias and redistribution layers, including building up layers such as via diffusion and deposition which may include one or more of physical vapor deposition (PVD), chemical vapor deposition (CVD), and atomic layer deposition (ALD). Part or all of a layer may also be removed using various processes such as photolithography, selective etching, wet etching using chemicals, dry etching using plasma, chemical-mechanical polishing (CMP), or any other suitable technique. Additionally, portions of the base substrate 102 may be removed using processes including mechanical drilling, laser removal, scribing, or other suitable techniques. Portions of the resulting surface of the base substrate 102 may include conductive elements such as traces, pads, and vias, which may be formed of conductive materials such as one or more metal including copper, aluminum, tungsten, as well as doped semiconductors, metal nitrides, doped carbon or other suitable materials. Portions of the resulting surface of the base substrate 102 may also include dielectric materials such as silicon dioxide, resins, adhesives, and epoxies, alone or in combination. Additionally, in some embodiments, additional layers may be formed on or within a surface of the base substrate 102, including additional circuit components such as routing layers, logical elements, and power distribution networks.

In the process 1100 at S1140, the one or more monolithic optical engines 109, the one or more processing units 105, the first support PIC 150 and the second support PIC 160 may be mounted on the base substrate 102. These elements are electrically coupled to the base substrate 102 via the one or more redistribution layers 401 using conductive connection such as pads, bumps, microbumps, pillars, balls, ball grids, microball arrays, and other forms such as C4 bumps, alone or in combination. In some embodiments, the one or more monolithic optical engines 109, the one or more processing units 105, the first support PIC 150 and the second support PIC 160 may be flipped prior to mounting on the base substrate 102.

In the process 1100 at S1150, the one or more monolithic optical engines 109, the one or more processing units 105, the first support PIC 150 and the second support PIC 160 may be further coupled with the base substrate 102. For example, a dielectric coupling may be formed between the base substrate 102 and one or more of the one or more monolithic optical engines 109, the one or more processing units 105, the first support PIC 150 and the second support PIC 160. A dielectric coupling may be in addition to the conductive coupling between the base substrate 102 and the mounted elements. The dielectric coupling may allow a dielectric bond to form between the base substrate 102 and mounted elements to provide mechanical, thermal, and electrical protection to the conductive coupling. For example, a dielectric coupling may provide additional mechanical adhesion between the mounted elements and the base substrate 102, physically securing the mounted elements in place as well as providing protection to the connection against physical shocks such as shaking the completed package. The dielectric coupling also may provide electric protection by providing a dielectric material between conductive coupling sections. The dielectric coupling may be formed from a material having a greater dielectric constant than the surrounding environment such as air or vacuum, and may provide electrical protections such as a preventing a short between conductive couplings, as well as preventing a short between the base substrate 102 and the mounted components, as well as protecting against incidental electrical shocks. The dielectric coupling may also provide thermal protection, as the material of the dielectric coupling may be used to either increase or decrease the thermal conduction between the base substrate 102 and the mounted elements, allowing routing of heat produced by the various components along desired pathways, such as to external surfaces, cooling devices, etc. In some embodiments, the dielectric coupling may also provide selective thermal routing for the conductive couplings, for example, controlling the heat dissipation from a conductive coupling distributing power away from more sensitive components.

A dielectric coupling may be formed between dielectric materials on opposing surfaces of a connection, for example silicon dioxide on a surface of the base substrate 102 and the one or more processing units 105. The dielectric coupling may be formed, for example, by thermally treating a mounted element on the base substrate 102 such that the dielectric material on the mounted element and base substrate 102 bond. Dielectric coupling may also be formed by providing a dielectric material between a mounted element and the base substrate 102 which may couple to dielectric materials on the respective surfaces. For example, an epoxy material, adhesive, elastomer, or resin may be placed between the base substrate 102 and the mounted element such that the dielectric material may bond to both surfaces. The dielectric material may be placed before, during, or after the formation of the conductive coupling. In some embodiments, the dielectric material may be an adhesive or epoxy material placed using an underfill method. The dielectric material may be subject to various processes to cure the epoxy or other adhesives used. In some embodiments, the curing may include thermal curing such as applying thermal energy such as a heater, as well as optical curing such as using a light source, as well as combinations thereof, as well as any other suitable curing method. Additionally, the curing process may be chosen such that the dielectric coupling and conductive coupling form a hybrid bond. A hybrid bond may be formed when both a dielectric bond is formed between opposing dielectric surfaces and a conductive bond is formed between opposing conductive surfaces. By bonding both conductive and dielectric surfaces, the total area bonded may be increased, and provide a mechanically stronger bond, and a mechanically resilient package.

In the process 1100 at S1160, the base substrate 102 and the one or more monolithic optical engines 109, the one or more processing units 105, the first support PIC 150 and the second support PIC 160 mounted on the base substrate 102 may be encapsulated by the molding layer 410. The encapsulation may be done by forming a layer of dielectric material such as silicon dioxide, resins, adhesives, glass, and epoxy molding compound or EMC, alone or in combination. In some embodiments, the molding layer 410 may fill otherwise empty space between the one or more monolithic optical engines 109, the one or more processing units 105, the first support PIC 150 and the second support PIC 160 mounted on the base substrate 102. In some embodiments, the molding layer 410 may also be formed around at least a portion of the outside surfaces of the one or more monolithic optical engines 109, the one or more processing units 105, the first support PIC 150 and the second support PIC 160 in addition to between the elements. The molding layer 410 may, in some embodiments, be formed to create at least one portion of an exterior surface for the hybrid packages. In some embodiments, the molding layer 410 may completely encapsulate a top surface of one or more of the one or more monolithic optical engines 109, the one or more processing units 105, the first support PIC 150 and the second support PIC 160, while in other embodiments the molding layer 410 may expose at least a portion of the one or more monolithic optical engines 109, the one or more processing units 105, the first support PIC 150 and the second support PIC 160. In some embodiments, the molding layer 410 may initially encapsulate one or more of the top surfaces of the one or more monolithic optical engines 109, the one or more processing units 105, the first support PIC 150 and the second support PIC 160 and then be subject to a planarization process to create a uniform top surface for the hybrid packages. Additionally, the molding layer 410 may include one or more recesses to provide access to the mounted elements, for example a recess may be formed within the molding layer 410 to allow an optical fiber to couple to the one or more optical connections 113.

In some embodiments, the molding layer 410 may be further modified, for example by placing a lid over at least a portion of the molding layer 410. The lid may be referred to as well as a plate. The lid may provide thermal or physical protection for the hybrid package and may be formed of a ceramic material or metal, such as glass, silicon dioxide, silicon dies, aluminum, copper, or any other suitable material. The lid may be physically and thermally coupled with the package such that the lid may provide a pathway for heat to transfer away from the package. This may be done using various methods, including the lid being formed of a metal acting as a heat spreader to the environment, which may be further enhanced by cooling structures such as radiative fins, heat sinks, heat exchangers, cooling plates, thermoelectric coolers, or any other suitable method.

While this specification may contain many specific implementation details, the implementation details should not be construed as limitations on the scope of any claimed subject matter but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific example teachings discussed above, but is instead defined by the following claims.

What is claimed is:

1. A device comprising:
a substrate supporting one or more processing units and one or more optical engines;
the substrate coupling the one or more processing units and the one or more optical engines;
the one or more optical engines including a first near compute device and a first bi-directional optical coupler;
the one or more optical engines being configured to convert an incoming optical signal received by the first bi-directional optical coupler to an electrical signal; and
the one or more optical engines being configured to route the electrical signal to the first near compute device or the one or more processing units via the one or more optical engines.

2. The device of claim 1, wherein:
the one or more optical engines comprise at least a first photonic circuit and at least a first electrical circuit,
the first photonic circuit including at least one selected from the group consisting of a waveguide, an optical filter, a polarizer, a serializer, a phase shifter, couplers, and a grating; and
the first electrical circuit including at least one selected from the group consisting of a photodetector, a transimpedance amplifier, and an analog-to-digital converter.

3. The device of claim 1, wherein:
the one or more optical engines comprise a first optical engine and a second optical engine,
the first optical engine including the first near compute device and the first bi-directional optical coupler,
the second optical engine including a second near compute device and a second bi-directional optical coupler,
the first optical engine being configured to route a first incoming optical signal received by the first bi-directional optical coupler to the first near compute device or the one or more processing units, and
the second optical engine being configured to route a second incoming optical signal received by the second bi-directional optical coupler to the second near compute device or the one or more processing units.

4. The device of claim 1, wherein the one or more optical engines has at least a first physical layer and a second physical layer, the first physical layer being coupled to the first near compute device and the second physical layer coupling to the one or more processing units.

5. The device of claim 1, wherein:
the one or more optical engines includes a first photonic circuit and a first electrical circuit, and
the first electrical circuit is arranged on a surface of the one or more optical engines between the first photonic circuit and the first near compute device.

6. The device of claim 1, wherein the first near compute device is communicatively coupled to a second near compute device via an optical fiber.

7. The device of claim 1, wherein
the first near compute device includes at least one selected from the group consisting of a memory device and a processing device.

8. A device comprising:
a substrate supporting a first processing unit, a first optical engine and a second optical engine;
the substrate coupling the first processing unit, the first optical engine and the second optical engine;
the first optical engine including a first near compute device and a first bi-directional optical coupler;
the second optical engine including a second near compute device and a second bi-directional optical coupler;
the first optical engine to route a first optical signal received by the first bi-directional optical coupler to the first near compute device or the first processing unit; and
the second optical engine to route a second optical signal received by the second bi-directional optical coupler to the second near compute device or the first processing unit.

9. The device of claim 8, wherein:
the first optical engine includes a first photonic circuit and a first electrical circuit,
the first electrical circuit is arranged on a surface of the first optical engine between the first photonic circuit and the first near compute device.

10. The device of claim 8, wherein:
the first optical engine comprises a first photonic circuit and a first electrical circuit,
the first photonic circuit including at least one selected from the group consisting of a waveguide, an optical filter, a polarizer, a serializer, a phase shifter, couplers, and a grating, and
the first electrical circuit including at least one selected from the group consisting of a photodetector, a transimpedance amplifier, and an analog-to-digital converter.

11. The device of claim 8, wherein
the first near compute device is communicatively coupled to a third near compute device via the first bi-directional optical coupler.

12. The device of claim 8, further comprising:
a first physical layer and a second physical layer on the first optical engine, the first physical layer being coupled to the first near compute device and the second physical layer being coupled to the first processing unit; and
a third physical layer and a fourth physical layer on the second optical engine, the third physical layer being coupled to the second near compute device and the fourth physical layer being coupled to the first processing unit.

13. The device of claim 8, wherein
the first near compute device includes at least one selected from the group consisting of a memory device and a processing device.

14. A system comprising:
a first package, the first package including a first optical engine and a first processing unit, the first optical engine with a first near compute device;
a second package, the second package including a second optical engine and a second processing unit, the second optical engine with a second near compute device; and
a first optical switch coupled to the first package via a first connection and the first optical switch coupled to the second package via a second connection,
wherein the first package is optically coupled to the second package via the first optical engine and the second optical engine.

15. The system of claim 14, wherein:
the first connection couples the first optical switch to a first photonic integrated circuit on the first package, and
the second connection couples the first optical switch to a second photonic integrated circuit on the second package.

16. The system of claim 14, wherein an optical coupling between the first package and the second package transmits a read signal to the first processing unit and a write signal to the first near compute device.

17. The system of claim 14, wherein an optical coupling between the first package and the second package transmits a write signal to the first near compute device and a write signal to the first processing unit.

18. The system of claim 14, wherein at least one of the first near compute device or the second near compute device comprise at least one memory device and at least one processing device.

19. The system of claim 14, wherein:
the first optical engine includes a first bi-directional optical coupler and the second optical engine includes a second bi-directional optical coupler, and
the first bi-directional optical coupler is optically coupled to the second bi-directional optical coupler.

20. The system of claim 14, wherein:
the first connection is an optical connection, and
the second connection is an optical connection.
